(19) United States
(12) Patent Application Publication
(10) Pub. No.: US 2025/0331217 A1
(43) Pub. Date: Oct. 23, 2025

(54) SEMICONDUCTOR DEVICE AND METHOD FOR MANUFACTURING THE SAME

(71) Applicant: KABUSHIKI KAISHA TOSHIBA, Tokyo (JP)

(72) Inventors: Yosuke KAJIWARA, Yokohama (JP); Tatsuo SHIMIZU, Shinagawa (JP)

(73) Assignee: KABUSHIKI KAISHA TOSHIBA, Tokyo (JP)

(21) Appl. No.: 19/039,040

(22) Filed: Jan. 28, 2025

(30) Foreign Application Priority Data
Apr. 18, 2024 (JP) 2024-067664

(51) Int. Cl. H10D 30/47; H10D 30/01; H10D 62/10; H10D 62/60; H10D 62/824; H10D 64/23; H10D 64/27

(52) U.S. Cl. CPC H10D 30/476; H10D 30/015; H10D 62/102; H10D 62/124; H10D 62/60; H10D 62/824; H10D 64/256; H10D 64/258; H10D 64/513; H10D 64/514; H10D 64/518

(57) ABSTRACT

According to one embodiment, a semiconductor device includes first to third electrodes and semiconductor member. The third electrode includes a first electrode portion. The semiconductor member includes first and second semiconductor regions. The first semiconductor region includes Alₓ₁Ga₁₋ₓ₁N (0≤x1<1) and includes carbon. The first semiconductor region includes first to sixth partial regions. A first hydrogen concentration in the sixth partial region is lower than a second hydrogen concentration in the fifth partial region. The second semiconductor region includes Alₓ₂Ga₁₋ₓ₂N (x1<x2≤1). The second semiconductor region includes a first semiconductor portion. A direction from the fifth partial region to the first semiconductor portion is along the second direction.

### CROSS-REFERENCE TO RELATED APPLICATIONS

This application is based upon and claims the benefit of priority from Japanese Patent Application No. 2024-067664, filed on Apr. 18, 2024; the entire contents of which are incorporated herein by reference.

### FIELD

Embodiments described herein relate generally to a semiconductor device and a method for manufacturing the same.

### BACKGROUND

For example, it is desired to improve the characteristics of semiconductor devices such as transistors.

### BRIEF DESCRIPTION OF THE DRAWINGS

FIG. 1 is a schematic cross-sectional view illustrating a semiconductor device according to a first embodiment;

FIG. 2 is a graph illustrating the characteristics of the semiconductor device;

FIG. 3 is a graph illustrating the characteristics of a semiconductor device;

FIG. 4 is a schematic cross-sectional view illustrating a semiconductor device according to the first embodiment;

FIG. 5 is a schematic cross-sectional view illustrating a semiconductor device according to the first embodiment;

FIG. 6 is a schematic cross-sectional view illustrating a semiconductor device according to the first embodiment;

FIG. 7 is a schematic cross-sectional view illustrating a semiconductor device according to a second embodiment;

FIG. 8 is a schematic cross-sectional view illustrating a semiconductor device according to the second embodiment;

FIGS. 9A to 9F are schematic cross-sectional views illustrating a method for manufacturing a semiconductor device according to a third embodiment; and

FIGS. 10A to 10E are schematic cross-sectional views illustrating the method for manufacturing a semiconductor device according to the third embodiment.

### DETAILED DESCRIPTION

According to one embodiment, a semiconductor device includes a first electrode, a second electrode, a third electrode, and semiconductor member. A direction from the first electrode to the second electrode is along a first direction. The third electrode includes a first electrode portion. A position of the first electrode portion in the first direction is between a position of the first electrode in the first direction and a position of the second electrode in the first direction. The semiconductor member includes a first semiconductor region and a second semiconductor region. The first semiconductor region includes Alₓ₁Ga₁₋ₓ₁N (0≤x1<1) and includes carbon. The first semiconductor region includes a first partial region, a second partial region, a third partial region, a fourth partial region, a fifth partial region, and a sixth partial region. A direction from the first partial region to the first electrode is along a second direction crossing the first direction. A direction from the second partial region to the second electrode is along the second direction. A direction from the third partial region to the first electrode portion is along the second direction. The fourth partial region is between the first partial region and the third partial region. The fifth partial region is between the third partial region and the second partial region. At least a part of the sixth partial region is between the first electrode portion and the fifth partial region in the first direction. A first hydrogen concentration in the sixth partial region is lower than a second hydrogen concentration in the fifth partial region. The second semiconductor region includes Alₓ₂Ga₁₋ₓ₂N (x1<x2≤1). The second semiconductor region includes a first semiconductor portion. A direction from the fifth partial region to the first semiconductor portion is along the second direction.

Various embodiments are described below with reference to the accompanying drawings.

The drawings are schematic and conceptual; and the relationships between the thickness and width of portions, the proportions of sizes among portions, etc., are not necessarily the same as the actual values. The dimensions and proportions may be illustrated differently among drawings, even for identical portions.

In the specification and drawings, components similar to those described previously or illustrated in an antecedent drawing are marked with like reference numerals, and a detailed description is omitted as appropriate.

### First Embodiment

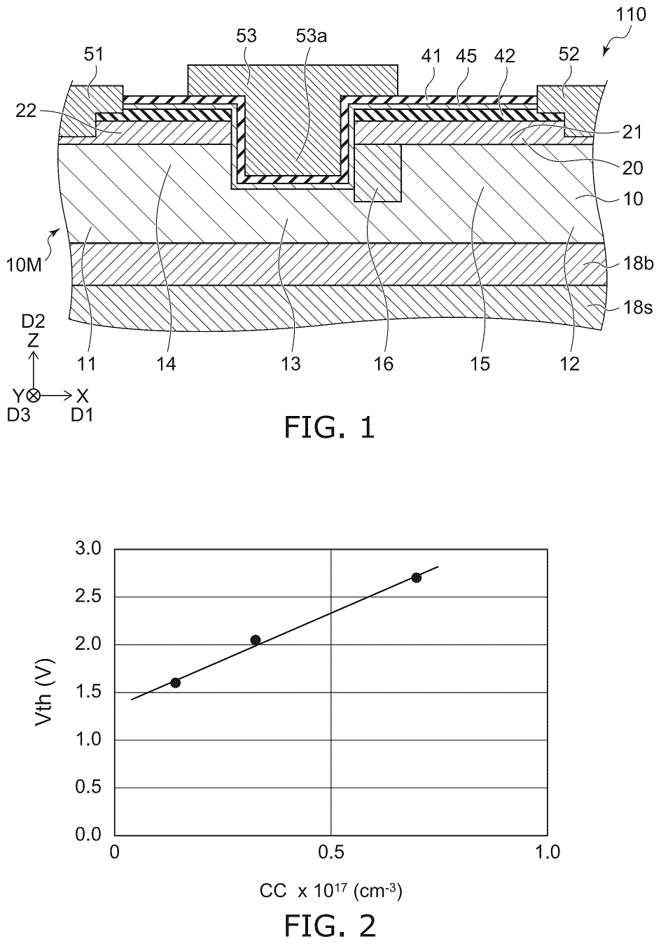

FIG. 1 is a schematic cross-sectional view illustrating a semiconductor device according to a first embodiment.

As shown in FIG. 1, a semiconductor device 110 according to the embodiment includes a first electrode 51, a second electrode 52, a third electrode 53, and a semiconductor member 10M.

A direction from the first electrode 51 to the second electrode 52 is along a first direction D1. In the example of FIG. 1, the first direction D1 is along an X-axis direction. A direction perpendicular to the X-axis direction is defined as a Z-axis direction. A direction perpendicular to the X-axis direction and the Z-axis direction is defined as a Y-axis direction.

The third electrode 53 includes a first electrode portion 53a. A position of the first electrode portion 53a in the first direction D1 is between a position of the first electrode 51 in the first direction D1 and a position of the second electrode 52 in the first direction D1.

The semiconductor member 10M includes s a first semiconductor region 10 and a second semiconductor region 20. The first semiconductor region 10 includes Alₓ₁Ga₁₋ₓ₁N (0≤x1<1). The first semiconductor region 10 includes carbon. The composition ratio x1 may be, for example, not less than 0 and not more than 0.13. The first semiconductor region 10 may be a GaN layer.

The first semiconductor region 10 includes a first partial region 11, a second partial region 12, a third partial region 13, a fourth partial region 14, a fifth partial region 15, and a sixth partial region 16. A direction from the first partial region 11 to the first electrode 51 is along a second direction D2 crossing the first direction D1. The second direction D2 is, for example, the Z-axis direction.

A direction from the second partial region 12 to the second electrode 52 is along the second direction D2. A direction from the third partial region 13 to the first electrode portion 53a is along the second direction D2. The first electrode 51, the second electrode 52, and the third electrode 53 may extend along a third direction D3. The third direction D3 crosses a plane including the first direction D1 and the second direction D2. The third direction D3 may be, for example, the Y-axis direction.

The fourth partial region 14 is between the first partial region 11 and the third partial region 13. The fifth partial region 15 is between the third partial region 13 and the second partial region 12. For example, a position of the fourth partial region 14 in the first direction D1 is between a position of the first partial region 11 in the first direction D1 and a position of the third partial region 13 in the first direction D1. A position of the fifth partial region 15 in the first direction D1 is between the position of the third partial region 13 in the first direction D1 and a position of the second partial region 12 in the first direction D1.

At least a part of the sixth partial region 16 is between the first electrode portion 53a and the fifth partial region 15 in the first direction D1. A hydrogen concentration in the sixth partial region 16 (first hydrogen concentration) is lower than a hydrogen concentration in the fifth partial region 15 (second hydrogen concentration).

The second semiconductor region 20 includes Alₓ₂Ga₁₋ₓ₂N (x1<x2≤1). The composition ratio x2 may be, for example, not less than 0.15 and not more than 0.4. The second semiconductor region 20 may be, for example, an AlGaN layer. The second semiconductor region 20 includes a first semiconductor portion 21. A direction from the fifth partial region 15 to the first semiconductor portion 21 is along the second direction D2.

Current flowing between the first electrode 51 and the second electrode 52 can be controlled by a potential of the third electrode 53. For example, the potential of the third electrode 53 may be based on a potential of the first electrode 51. For example, the first electrode 51 is one of a source electrode and a drain electrode. The second electrode 52 is the other one of the source electrode and the drain electrode. The third electrode 53 is a gate electrode. The semiconductor device 110 is, for example, a transistor.

The first semiconductor region 10 includes a portion facing the second semiconductor region 20. A carrier region is formed in this portion. The carrier region is, for example, a two-dimensional electron gas. The semiconductor device is, for example, a HEMT (High Electron Mobility Transistor).

In the embodiment, it has been found that a high threshold voltage can be obtained by carbon included in the first semiconductor region 10. Furthermore, it has been found that the threshold voltage also changes depending on the concentration of hydrogen in the first semiconductor region 10.

FIG. 2 is a graph illustrating the characteristics of the semiconductor device.

FIG. 2 illustrates measurement results of the threshold voltage in samples in which the entire of the first semiconductor region 10 includes carbon in the configuration of the semiconductor device 110 described above. In the samples, the first semiconductor region 10 does not substantially include hydrogen. The horizontal axis in FIG. 2 is the carbon concentration CC. The vertical axis is the threshold voltage Vth. As shown in FIG. 2, when the carbon concentration CC is high, the threshold voltage Vth being high can be obtained.

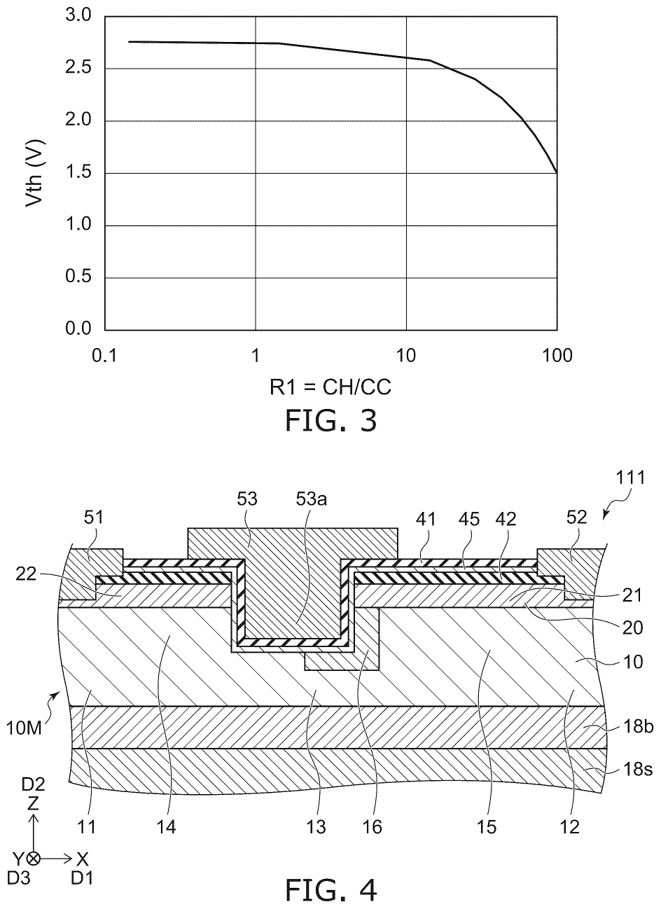

FIG. 3 is a graph illustrating the characteristics of a semiconductor device.

FIG. 3 illustrates the threshold voltage when the entre of the first semiconductor region 10 includes carbon and hydrogen in the configuration of the semiconductor device 110 described above. In this example, the carbon concentration CC is constant at 7×10¹⁶/cm³. The horizontal axis in FIG. 3 is a concentration ratio R1. The concentration ratio R1 is the ratio of the hydrogen concentration CH to the carbon concentration CC. The vertical axis is the threshold voltage Vth. As shown in FIG. 2, the threshold voltage Vth being high is obtained when the concentration ratio R1 is low. When the concentration ratio R1 is high, the threshold voltage Vth decreases.

In the embodiment, if a high threshold voltage is obtained at one position between the first electrode 51 and the second electrode 52, a high threshold voltage is obtained for the entire of the semiconductor device 110. It is preferable that the threshold voltage is low except at specific positions where a high threshold voltage can be obtained. This results in low on-resistance.

In the embodiment, the first hydrogen concentration in the sixth partial region 16 is lower than the second hydrogen concentration in the fifth partial region 15. A high threshold value is obtained in the sixth partial region 16 due to the sixth partial region 16 having a low hydrogen concentration. On the other hand, the fifth partial region 15 with a high hydrogen concentration provides low on-resistance. In the embodiment, a high threshold voltage and a low on-resistance can be obtained. By a high hydrogen concentration in the fifth partial region 15, for example, the number of traps in the fifth partial region 15 can be reduced. With fewer traps, current collapse can be reduced. According to the embodiment, a semiconductor device whose characteristics can be improved can be provided.

In the embodiment, the concentration ratio R1 in the sixth partial region 16 is preferably 1/10 or less. This results in a high threshold voltage (see FIG. 3). For example, the first hydrogen concentration is preferably 1/10 or less of a first carbon concentration in the sixth partial region 16.

In the embodiment, the concentration ratio R1 in the fifth partial region 15 is preferably ½ or more. For example, the threshold voltage Vth being low can be obtained (see FIG. 3). Low on-resistance can be obtained. For example, the second hydrogen concentration is preferably ½ or more of a second carbon concentration in the fifth partial region 15.

In the embodiment, the carbon concentration may be substantially constant in the sixth partial region 16 and the fifth partial region 15. For example, a ratio of a first absolute value of a first difference between the first carbon concentration and the second carbon concentration to the second carbon concentration may be 0.2 or less.

In the embodiment, the second hydrogen concentration may be bot less than 5 times and not more than 100 times the first hydrogen concentration.

As shown in FIG. 1, a distance (first distance) along the first direction D1 between the first electrode 51 and the first electrode portion 53a is preferably shorter than a distance (second distance) along the first direction D1 between the first electrode portion 53a and the second electrode 52. A high breakdown voltage is easily obtained. The first electrode 51 is a source electrode, and the second electrode 52 is a drain electrode.

In the semiconductor device 110, the second semiconductor region 20 may further include a second semiconductor portion 22. A direction from the fourth partial region 14 to the second semiconductor portion 22 is along the second direction D2.

The semiconductor device 110 may further include a first insulating member 41. At least a part of the first insulating member 41 is provided between the third electrode 53 and the semiconductor member 10M.

The semiconductor device 110 may further include a first compound member 45. The first compound member 45 includes Al_{z1}Ga_{1-z1}N (0<z1≤1). The composition ratio z1 may be, for example, not less than 0.7 and not more than 1. The first compound member 45 may be, for example, an AlN layer. The first compound member 45 is provided between the semiconductor member 10M and the first insulating member 41. The first insulating member 41 includes silicon and oxygen, for example.

The semiconductor device 110 may further include a second insulating member 42. The first semiconductor portion 21 is provided between the fifth partial region 15 and at least a part of the second insulating member 42 in the second direction D2. The second semiconductor portion 22 is provided between the fourth partial region 14 and at least a part of the second insulating member 42 in the second direction D2. The second insulating member 42 includes silicon and nitrogen, for example. The first semiconductor portion 21 is protected by the second insulating member 42. It is easy to obtain high breakdown voltage. Current collapse can be reduced.

As shown in FIG. 1, the semiconductor member 10M may include a base 18s and a nitride layer 18b. The nitride layer 18b is provided between the base 18s and the second semiconductor region 20. The first semiconductor region 10 is provided between the nitride layer 18b and the second semiconductor region 20. The base 18s may include, for example, a silicon substrate. The nitride layer 18b may include Al, Ga, and N. The nitride layer 18b is, for example, a buffer layer.

FIG. 4 is a schematic cross-sectional view illustrating a semiconductor device according to the first embodiment.

As shown in FIG. 4, in a semiconductor device 111 according to the embodiment, the shape of the sixth partial region 16 is different from that in the semiconductor device 110. The configuration of the semiconductor device 111 except for this may be the same as the configuration of the semiconductor device 110.

In the semiconductor device 111, a part of the sixth partial region 16 is located between the third partial region 13 and the first electrode portion 53a in the second direction D2. A high threshold voltage can be obtained more reliably. Leakage current during off-operation can be reduced.

The hydrogen concentration (first hydrogen concentration) in the sixth partial region 16 may be lower than the hydrogen concentration in the third partial region 13. When a high voltage is applied to the second electrode 52, the electric field in the sixth partial region 16 increases. When the hydrogen concentration in the sixth partial region 16 is high, hydrogen bonds are likely to be broken due to a strong electric field, hydrogen is likely to diffuse, and device operation is likely to become unstable. Low hydrogen concentration facilitates stable device operation. When the hydrogen concentration in the sixth partial region 16 is high, leakage current tends to increase. By the hydrogen concentration in the sixth partial region 16 being low, leakage current during off-operation can be reduced.

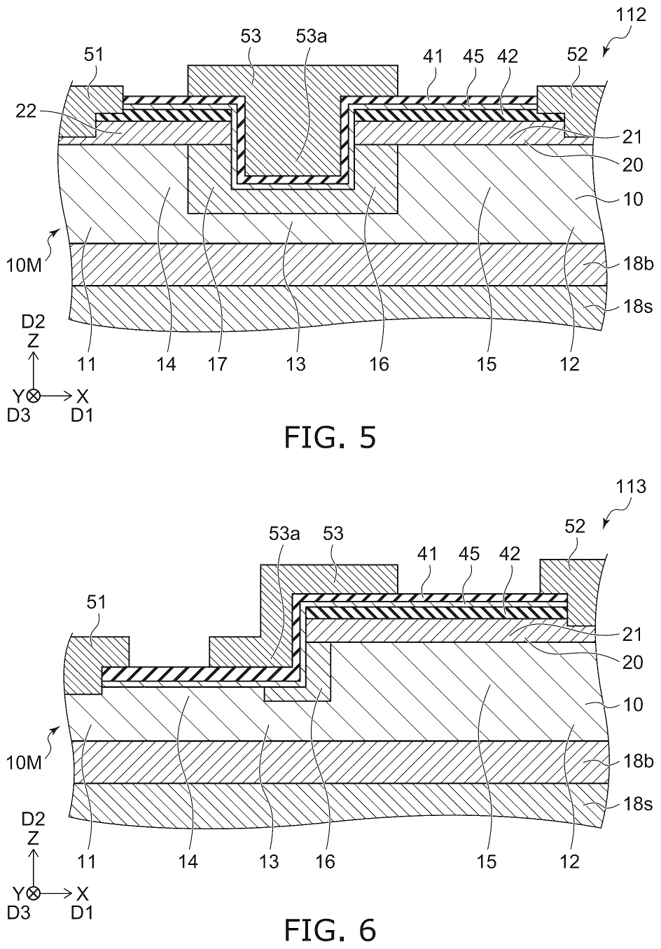

FIG. 5 is a schematic cross-sectional view illustrating a semiconductor device according to the first embodiment.

As shown in FIG. 5, in a semiconductor device 112 according to the embodiment, the first semiconductor region 10 further includes a seventh partial region 17. The configuration of the semiconductor device 112 except for this may be the same as the configuration of the semiconductor device 110 or the semiconductor device 111.

In the semiconductor device 112, the second semiconductor region 20 includes the second semiconductor portion 22. The direction from the fourth partial region 14 to the second semiconductor portion 22 is along the second direction D2. The direction from the seventh partial region 17 to the second semiconductor portion 22 is along the second direction D2.

At least a part of the seventh partial region 17 is located between the fourth partial region 14 and the first electrode portion 53a in the first direction D1. A hydrogen concentration in the seventh partial region 17 (third hydrogen concentration) is lower than a hydrogen concentration in the fourth partial region 14 (fourth hydrogen concentration). A high threshold voltage and low on-resistance can be obtained.

For example, the third hydrogen concentration in the seventh partial region 17 is preferably 1/10 or less of a carbon concentration (third carbon concentration) in the seventh partial region 17. The fourth hydrogen concentration in the fourth partial region 14 is preferably not less than ½ of a fourth carbon concentration in the fourth partial region 14. A high threshold voltage and a low on-resistance are easily obtained.

For example, a ratio of the second absolute value of a second difference between the third carbon concentration and the fourth carbon concentration to the fourth carbon concentration may be 0.2 or less.

In the semiconductor device 112, at least one of the sixth partial region 16 or the seventh partial region 17 may be provided between the third partial region 13 and the first electrode portion 53a.

In the semiconductor device 110, the semiconductor device 111, and the semiconductor device 112, the first electrode portion 53a is located between the second semiconductor portion 22 and the first semiconductor portion 21 in the first direction D1.

In the semiconductor device 110, the semiconductor device 111, and the semiconductor device 112, the sixth partial region 16 overlaps at least a part of the third electrode 53 in the second direction D2. The fifth partial region 15 may not overlap the third electrode 53 in the second direction D2.

FIG. 6 is a schematic cross-sectional view illustrating a semiconductor device according to the first embodiment.

As shown in FIG. 6, in a semiconductor device 113 according to the embodiment, the position of the first electrode 51 in the Z-axis direction is different from that in the semiconductor device 110 and the like. The configuration of the semiconductor device 113 except for this may be the same as the configuration of the semiconductor device 110 and the like.

In the semiconductor device 113 as well, the first hydrogen concentration in the sixth partial region 16 is lower than the second hydrogen concentration in the fifth partial region 15. In the semiconductor device 113 as well, a high threshold voltage and low on-resistance can be obtained.

The semiconductor device 113 further includes the second insulating member 42. The first semiconductor portion 21 is provided between the fifth partial region 15 and at least a part of the second insulating member 42 in the second direction D2. The second insulating member 42 includes silicon and nitrogen, for example. The first semiconductor portion 21 is protected by the second insulating member 42. It is easy to obtain high breakdown voltage. Current collapse can be reduced.

### Second Embodiment

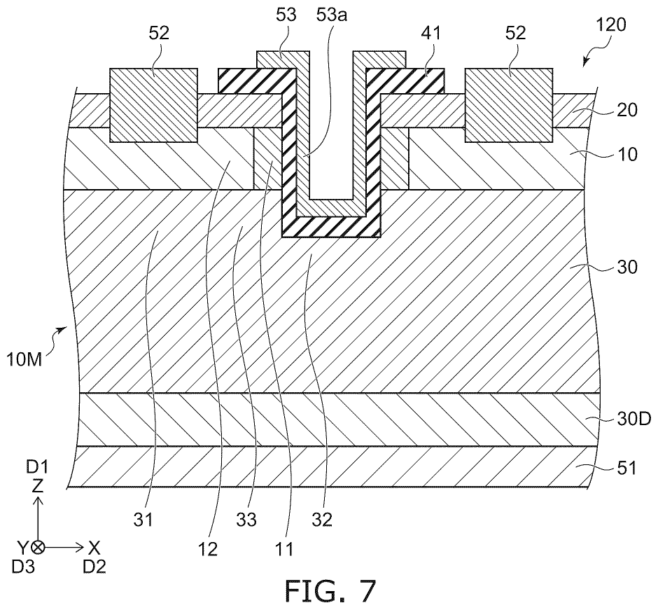

FIG. 7 is a schematic cross-sectional view illustrating a semiconductor device according to a second embodiment.

As shown in FIG. 7, a semiconductor device 120 according to the embodiment includes the first electrode 51, the second electrode 52, the third electrode 53, and the semiconductor member 10M. The third electrode 53 includes the first electrode portion 53a.

The semiconductor member 10M includes the first semiconductor region 10, the second semiconductor region 20, and a third semiconductor region 30. The first semiconductor region 10 includes Alₓ₁Ga₁₋ₓ₁N (0≤x1<1). The first semiconductor region 10 may be, for example, a GaN layer. The first semiconductor region 10 includes carbon. The second semiconductor region 20 includes Alₓ₂Ga₁₋ₓ₂N (x1<x2≤1). The second semiconductor region 20 may be, for example, an AlGaN layer. The third semiconductor region 30 includes Alₓ₃Ga₁₋ₓ₃N (0≤x3<1). The third semiconductor region 30 may be, for example, a GaN layer. Third semiconductor region 30 includes silicon. The third semiconductor region 30 is n-type.

A second direction D2 from the second electrode 52 to the first electrode portion 53a crosses a first direction D1 from the first electrode 51 to the second electrode 52. The first direction D1 is, for example, the Z-axis direction. The second direction D2 is, for example, the X-axis direction.

For example, the first semiconductor region 10 is located between the third semiconductor region 30 and the second semiconductor region 20 in the first direction D1.

The third semiconductor region 30 includes a first portion 31, a second portion 32, and a third portion 33. A direction from the first portion 31 to the second electrode 52 is along the first direction D1. A direction from the second portion 32 to the first electrode portion 53a is along the first direction D1.

The third portion 33 is located between the first portion 31 and the second portion 32. A position of the third portion 33 in the second direction D2 is between a position of the first portion 31 in the second direction D2 and a position of the second portion 32 in the second direction D2.

The first semiconductor region 10 includes a first partial region 11 and a second partial region 12. The first partial region 11 is located between the second partial region 12 and the first electrode portion 53a in the second direction D2. The first partial region 11 and the second partial region 12 are located between the third portion 33 and the second semiconductor region 20 in the first direction D1.

The first hydrogen concentration in the first partial region 11 is lower than the second hydrogen concentration in the second partial region 12. For example, a high threshold voltage can be obtained in the first partial region 11 by the first partial region 11 having a low hydrogen concentration. On the other hand, by the second partial region 12 with a high hydrogen concentration, low on-resistance can be obtained. In the embodiment, high threshold voltage and low on-resistance can be provided. According to the embodiment, a semiconductor device whose characteristics can be improved can be provided.

The semiconductor device 120 may further include the first insulating member 41. At least a part of the first insulating member 41 is provided between the third electrode 53 and the semiconductor member 10M.

The semiconductor device 120 may further include a fourth semiconductor region 30D. The fourth semiconductor region 30D is provided between the first electrode 51 and the third semiconductor region 30. A silicon concentration in the fourth semiconductor region 30D is higher than a silicon concentration in the third semiconductor region 30. The third semiconductor region 30 is, for example, an n⁻-layer. The fourth semiconductor region 30D is, for example, an n⁺-layer. Lower on-resistance can be obtained.

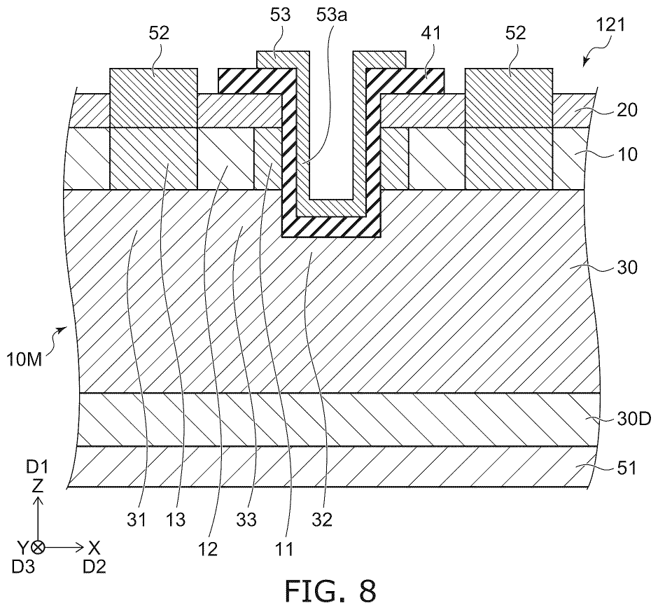

FIG. 8 is a schematic cross-sectional view illustrating a semiconductor device according to the second embodiment.

As shown in FIG. 8, in a semiconductor device 121 according to the embodiment, the first semiconductor region 10 includes a third partial region 13. The configuration of the semiconductor device 121 except for this may be the same as the configuration of the semiconductor device 120.

In the semiconductor device 121, the third partial region 13 is located between the first portion 31 and the first electrode 51 in the first direction D1. The third hydrogen concentration in the third partial region 13 is lower than the second hydrogen concentration in the second partial region 12. For example, it is easy to obtain a low leakage current between the second electrode 52 and the first semiconductor region 10. Operation during switching is easy to stabilize.

### Third Embodiment

The third embodiment relates to a method for manufacturing a semiconductor device.

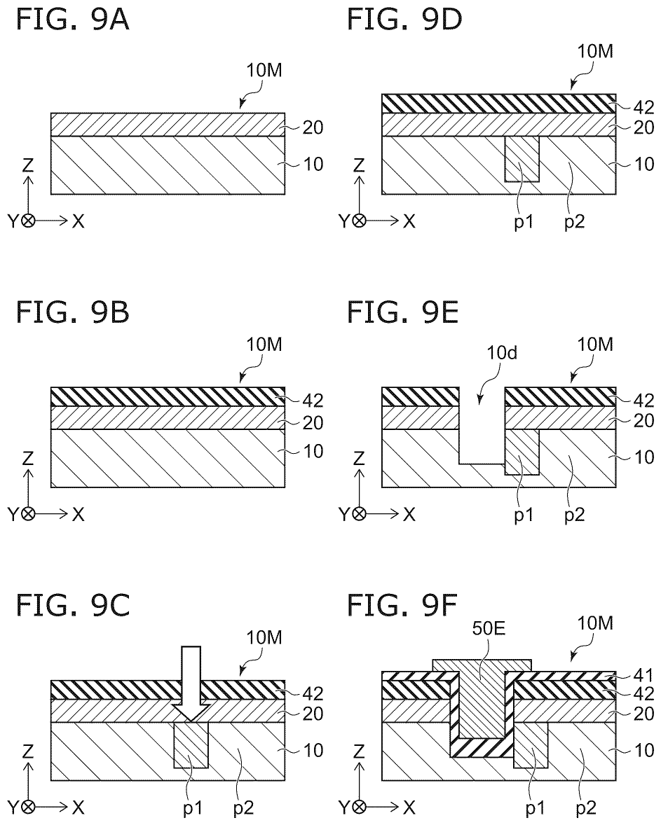

FIGS. 9A to 9F are schematic cross-sectional views illustrating a method for manufacturing a semiconductor device according to the third embodiment.

As shown in FIG. 9A, the semiconductor member 10M is prepared. The semiconductor member 10M includes the first semiconductor region 10 and a second semiconductor region 20. The first semiconductor region 10 includes Alₓ₁Ga₁₋ₓ₁N (0≤x1<1). The first semiconductor region 10 includes hydrogen and carbon. The second semiconductor region 20 includes Alₓ₂Ga₁₋ₓ₂N (x1<x2≤1). For example, the second semiconductor region 20 is provided on the first semiconductor region 10.

As shown in FIG. 9B, the second insulating member 42 (for example, a protective layer) may be provided on the second semiconductor region 20.

As shown in FIG. 9C, a part of the hydrogen included in the first region p1 of the first semiconductor region 10 is removed. For example, the part of the hydrogen included in the first region p1 is removed by local heating by laser irradiation. Hydrogen included in the second region p2 of the first semiconductor region 10 is not substantially removed.

As a result, multiple regions with different hydrogen concentrations are formed as shown in FIG. 9D. The first region hydrogen concentration in the first region p1 can be lower than the second region hydrogen concentration in the second region p2 of the first semiconductor region 10.

As shown in FIG. 9E, a part of the second semiconductor region 20 and a part of the second region p2 are removed to form a recess 10d.

As shown in FIG. 9(f), an electrode 50E is formed in the recess 10d. The first insulating member 41 may be formed in the recess 10d before forming the electrode 50E. The electrode 50E becomes, for example, the third electrode 53. Further, by forming the first electrode 51 and the second electrode 52, for example, the semiconductor device 110 is obtained.

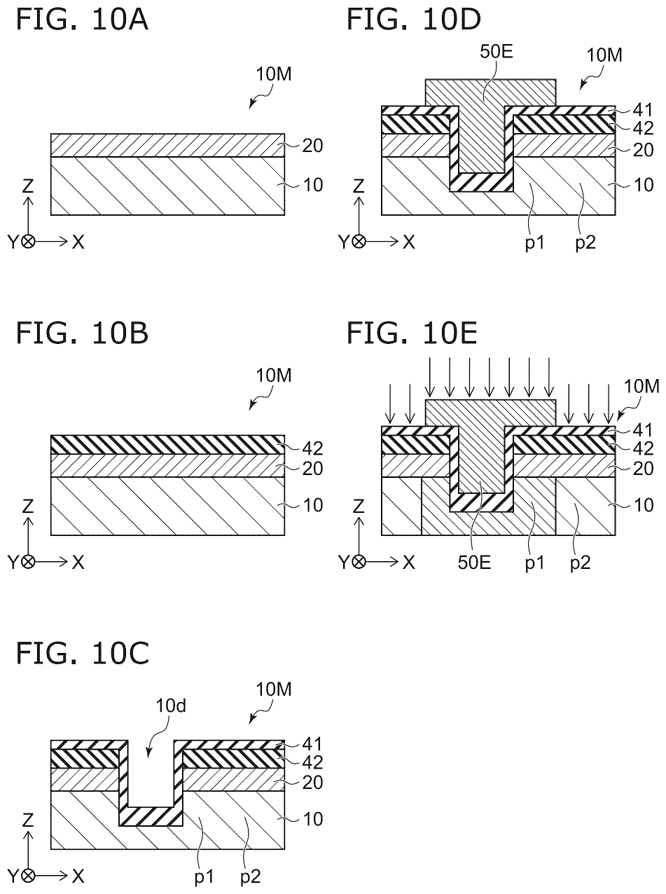

FIGS. 10A to 10E are schematic cross-sectional views illustrating the method for manufacturing a semiconductor device according to the third embodiment.

As shown in FIG. 10A, the semiconductor member 10M is prepared. The semiconductor member 10M includes a first semiconductor region 10 and a second semiconductor region 20. The first semiconductor region 10 includes Alₓ₁Ga₁₋ₓ₁N (0≤x1<1). The first semiconductor region 10 includes hydrogen and carbon. The second semiconductor region 20 includes Alₓ₂Ga₁₋ₓ₂N (x1<x2≤1). For example, the second semiconductor region 20 is provided on the first semiconductor region 10.

As shown in FIG. 10B, the second insulating member 42 (for example, a protective layer) may be provided on the second semiconductor region 20.

As shown in FIG. 10C, a part of the second semiconductor region 20 and a part of the first semiconductor region 10 are removed to form a recess 10d. The first insulating member 41 may be formed inside the recess 10d.

As shown in FIG. 10D, an electrode 50E is formed in the recess 10d and on a part of the second semiconductor region 20. The first semiconductor region 10 includes a first region p1 that overlaps the electrode 50E and a second region p2 that does not overlap the electrode 50E.

As shown in FIG. 10E, hydrogen is introduced into the semiconductor member 10M using the electrode 50E as a mask. For example, ion implantation is performed. Thereby, the first region hydrogen concentration in the first region p1 can be made lower than the second region hydrogen concentration in the second region p2.

In the embodiment, information regarding the shape of the semiconductor region, etc. is obtained, for example, by electron microscopic observation. Information regarding the composition and element concentration in the semiconductor region can be obtained by, for example, EDX (Energy Dispersive X-ray Spectroscopy) or SIMS (Secondary Ion Mass Spectrometry). Information regarding the composition in the semiconductor region may be obtained by, for example, reciprocal space mapping.

The embodiments may include the following Technical proposals:

### Technical Proposal 1

A semiconductor device, comprising:
a first electrode;
a second electrode, a direction from the first electrode to the second electrode being along a first direction;
a third electrode including a first electrode portion, a position of the first electrode portion in the first direction being between a position of the first electrode in the first direction and a position of the second electrode in the first direction; and
a semiconductor member,
the semiconductor member including:
   a first semiconductor region including Alₓ₁Ga₁₋ₓ₁N (0≤x1<1) and including carbon, the first semiconductor region including a first partial region, a second partial region, a third partial region, a fourth partial region, a fifth partial region, and a sixth partial region, a direction from the first partial region to the first electrode being along a second direction crossing the first direction, a direction from the second partial region to the second electrode being along the second direction, a direction from the third partial region to the first electrode portion being along the second direction, the fourth partial region being between the first partial region and the third partial region, the fifth partial region being between the third partial region and the second partial region, at least a part of the sixth partial region being between the first electrode portion and the fifth partial region in the first direction, a first hydrogen concentration in the sixth partial region being lower than a second hydrogen concentration in the fifth partial region, and
   a second semiconductor region including Alₓ₂Ga₁₋ₓ₂N (x1<x2≤1), the second semiconductor region including a first semiconductor portion, a direction from the fifth partial region to the first semiconductor portion being along the second direction.

### Technical Proposal 2

The semiconductor device according to Technical proposal 1, wherein
the first hydrogen concentration is 1/10 or less of a first carbon concentration in the sixth partial region.

### Technical Proposal 3

The semiconductor device according to Technical proposal 1 or 2, wherein
the second hydrogen concentration is ½ or more of a second carbon concentration in the fifth partial region.

### Technical Proposal 4

The semiconductor device according to Technical proposal 3, wherein
a ratio of a first absolute value of a first difference between the first carbon concentration and the second carbon concentration to the second carbon concentration is 0.2 or less.

### Technical Proposal 5

The semiconductor device according to any one of Technical proposals 1-4, wherein
the second hydrogen concentration is not less than 5 times the first hydrogen concentration.

### Technical Proposal 6

The semiconductor device according to any one of Technical proposals 1-5, wherein
a first distance along the first direction between the first electrode and the first electrode portion is shorter than a second distance along the first direction between the first electrode portion and the second electrode.

### Technical Proposal 7

The semiconductor device according to any one of Technical proposals 1-6, wherein
a part of the sixth partial region is between the third partial region and the first electrode portion in the second direction.

### Technical Proposal 8

The semiconductor device according to any one of Technical proposals 1-7, wherein
the second semiconductor region further includes a second semiconductor portion, and
a direction from the fourth partial region to the second semiconductor portion is along the second direction.

### Technical Proposal 9

The semiconductor device according to Technical proposal 8, wherein
the first semiconductor region further includes a seventh partial region,
at least a part of the seventh partial region is between the fourth partial region and the first electrode portion in the first direction, and
a third hydrogen concentration in the seventh partial region is lower than a fourth hydrogen concentration in the fourth partial region.

### Technical Proposal 10

The semiconductor device according to Technical proposal 9, wherein
the third hydrogen concentration is 1/10 or less of a third carbon concentration in the seventh partial region.

### Technical Proposal 11

The semiconductor device according to Technical proposal 10, wherein
the fourth hydrogen concentration is ½ or more of a fourth carbon concentration in the fourth partial region.

### Technical Proposal 12

The semiconductor device according to Technical proposal 11, wherein
a ratio of a second absolute value of a second difference between the third carbon concentration and the fourth carbon concentration to the fourth carbon concentration is 0.2 or less.

### Technical Proposal 13

The semiconductor device according to any one of Technical proposals 8-12, wherein
the first electrode portion is between the second semiconductor portion and the first semiconductor portion in the first direction.

### Technical Proposal 14

The semiconductor device according to any one of Technical proposals 1-12, further comprising:
a first insulating member,
at least a part of the first insulating member being provided between the third electrode and the semiconductor member.

### Technical Proposal 15

The semiconductor device according to Technical proposal 14, further comprising:
a first compound member including Al_{z1}Ga_{1-z1}N (0<z1≤1),
the first compound member being provided between the semiconductor member and the first insulating member.

### Technical Proposal 16

The semiconductor device according to Technical proposal 14 or 15, further comprising:
a second insulation member,
the first semiconductor portion being provided between the fifth partial region and at least a part of the second insulating member in the second direction.

### Technical Proposal 17

A semiconductor device, comprising:
a first electrode;
a second electrode;
a third electrode including a first electrode portion; and
a semiconductor member,
the semiconductor member including:
   a first semiconductor region including Alₓ₁Ga₁₋ₓ₁N (0≤x1<1) and including carbon,
   a second semiconductor region including Alₓ₂Ga₁₋ₓ₂N (x1<x2≤1), and
   a third semiconductor region including Alₓ₃Ga₁₋ₓ₃N (0≤x3<1) and including silicon,
a second direction from the second electrode to the first electrode portion crossing a first direction from the first electrode to the second electrode,
the third semiconductor region including a first portion, a second portion, and a third portion,
a direction from the first portion to the second electrode being along the first direction,
a direction from the second portion to the first electrode portion being along the first direction,
the third portion being between the first portion and the second portion,
the first semiconductor region including a first partial region and a second partial region,
the first partial region being between the second partial region and the first electrode portion in the second direction,
the first partial region and the second partial region being between the third portion and the second semiconductor region in the first direction,
a first hydrogen concentration in the first partial region being lower than a second hydrogen concentration in the second partial region.

### Technical Proposal 18

The semiconductor device according to Technical proposal 17, wherein
the first semiconductor region further includes a third partial region,
the third partial region is between the first portion and the first electrode in the first direction,
a third hydrogen concentration in the third partial region is lower than the second hydrogen concentration.

### Technical Proposal 19

A method for manufacturing a semiconductor device, the method comprising:
preparing a semiconductor member including a first semiconductor region and a second semiconductor region, the first semiconductor region including Alₓ₁Ga₁₋ₓ₁N (0≤x1<1) and including hydrogen and carbon, the second semiconductor region including Alₓ₂Ga₁₋ₓ₂N (x1<x2≤1);
removing a part of hydrogen included in a first region of the first semiconductor region to cause a first region hydrogen concentration in the first region being lower than a second region hydrogen concentration in a second region of the first semiconductor region; and
forming a recess by removing a part of the second semiconductor region and a part of the second region, and forming an electrode in the recess.

### Technical Proposal 20

A method for manufacturing a semiconductor device, the method comprising:
preparing a semiconductor member including a first semiconductor region and a second semiconductor region, the first semiconductor region including Alₓ₁Ga₁₋ₓ₁N (0≤x1<1) and including hydrogen and carbon, the second semiconductor region including Alₓ₂Ga₁₋ₓ₂N (x1<x2≤1);
forming a recess by removing a part of the second semiconductor region and a part of the first semiconductor region;
forming an electrode in a part of the recess and on the second semiconductor region, the first semiconductor region includes a first region overlapping the electrode and a second region not overlapping the electrode; and
introducing hydrogen into the semiconductor member using the electrode as a mask, a first region hydrogen concentration in the first region being lower than a second region hydrogen concentration in the second region.

According to the embodiment, a semiconductor device whose characteristics can be improved and a method for manufacturing the same are provided.

In the present specification, the term “electrically connected state” includes a state in which a plurality of conductors are physically in contact and a current flows between the plurality of conductors. The “state of being electrically connected” includes a state in which another conductor is inserted between the plurality of conductors and a current flows between the plurality of conductors.

In the specification of the application, “perpendicular” and “parallel” refer to not only strictly perpendicular and strictly parallel but also include, for example, the fluctuation due to manufacturing processes, etc. It is sufficient to be substantially perpendicular and substantially parallel.

Hereinabove, exemplary embodiments of the invention are described with reference to specific examples. However, the embodiments of the invention are not limited to these specific examples. For example, one skilled in the art may similarly practice the invention by appropriately selecting specific configurations of components included in the semiconductor devices such as electrodes, semiconductor members, semiconductor regions, bases, etc., from known art. Such practice is included in the scope of the invention to the extent that similar effects thereto are obtained.

Further, any two or more components of the specific examples may be combined within the extent of technical feasibility and are included in the scope of the invention to the extent that the purport of the invention is included.

Moreover, all semiconductor devices and all methods for manufacturing the same practicable by an appropriate design modification by one skilled in the art based on the semiconductor devices and the methods for manufacturing the same described above as embodiments of the invention also are within the scope of the invention to the extent that the purport of the invention is included.

Various other variations and modifications can be conceived by those skilled in the art within the spirit of the invention, and it is understood that such variations and modifications are also encompassed within the scope of the invention.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the invention.

What is claimed is:

1. A semiconductor device, comprising:
a first electrode;
a second electrode, a direction from the first electrode to the second electrode being along a first direction;
a third electrode including a first electrode portion, a position of the first electrode portion in the first direction being between a position of the first electrode in the first direction and a position of the second electrode in the first direction; and
a semiconductor member,
the semiconductor member including:
a first semiconductor region including Alₓ₁Ga₁₋ₓ₁N (0≤x1<1) and including carbon, the first semiconductor region including a first partial region, a second partial region, a third partial region, a fourth partial region, a fifth partial region, and a sixth partial region, a direction from the first partial region to the first electrode being along a second direction crossing the first direction, a direction from the second partial region to the second electrode being along the second direction, a direction from the third partial region to the first electrode portion being along the second direction, the fourth partial region being between the first partial region and the third partial region, the fifth partial region being between the third partial region and the second partial region, at least a part of the sixth partial region being between the first electrode portion and the fifth partial region in the first direction, a first hydrogen concentration in the sixth partial region being lower than a second hydrogen concentration in the fifth partial region, and
a second semiconductor region including Alₓ₂Ga₁₋ₓ₂N (x1<x2≤1), the second semiconductor region including a first semiconductor portion, a direction from the fifth partial region to the first semiconductor portion being along the second direction.

2. The semiconductor device according to claim 1, wherein
the first hydrogen concentration is 1/10 or less of a first carbon concentration in the sixth partial region.

3. The semiconductor device according to claim 1, wherein
the second hydrogen concentration is ½ or more of a second carbon concentration in the fifth partial region.

4. The semiconductor device according to claim 3, wherein
a ratio of a first absolute value of a first difference between the first carbon concentration and the second carbon concentration to the second carbon concentration is 0.2 or less.

5. The semiconductor device according to claim 1, wherein
the second hydrogen concentration is not less than 5 times the first hydrogen concentration.

6. The semiconductor device according to claim 1, wherein
a first distance along the first direction between the first electrode and the first electrode portion is shorter than a second distance along the first direction between the first electrode portion and the second electrode.

7. The semiconductor device according to claim 1, wherein
a part of the sixth partial region is between the third partial region and the first electrode portion in the second direction.

8. The semiconductor device according to claim 1, wherein
the second semiconductor region further includes a second semiconductor portion, and
a direction from the fourth partial region to the second semiconductor portion is along the second direction.

9. The semiconductor device according to claim 8, wherein
the first semiconductor region further includes a seventh partial region,
at least a part of the seventh partial region is between the fourth partial region and the first electrode portion in the first direction, and
a third hydrogen concentration in the seventh partial region is lower than a fourth hydrogen concentration in the fourth partial region.

10. The semiconductor device according to claim 9, wherein
the third hydrogen concentration is 1/10 or less of a third carbon concentration in the seventh partial region.

11. The semiconductor device according to claim 10, wherein
the fourth hydrogen concentration is ½ or more of a fourth carbon concentration in the fourth partial region.

12. The semiconductor device according to claim 11, wherein
a ratio of a second absolute value of a second difference between the third carbon concentration and the fourth carbon concentration to the fourth carbon concentration is 0.2 or less.

13. The semiconductor device according to claim 8, wherein
the first electrode portion is between the second semiconductor portion and the first semiconductor portion in the first direction.

14. The semiconductor device according to claim 1, further comprising:
a first insulating member,
at least a part of the first insulating member being provided between the third electrode and the semiconductor member.

15. The semiconductor device according to claim 14, further comprising:
a first compound member including Al_{z1}Ga_{1-z1}N (0<z1≤1),
the first compound member being provided between the semiconductor member and the first insulating member.

16. The semiconductor device according to claim 14, further comprising:
a second insulation member,
the first semiconductor portion being provided between the fifth partial region and at least a part of the second insulating member in the second direction.

17. A semiconductor device, comprising:
a first electrode;
a second electrode;
a third electrode including a first electrode portion; and
a semiconductor member,
the semiconductor member including:
a first semiconductor region including Alₓ₁Ga₁₋ₓ₁N (0≤x1<1) and including carbon,
a second semiconductor region including Alₓ₂Ga₁₋ₓ₂N (x1<x2≤1), and
a third semiconductor region including Alₓ₃Ga₁₋ₓ₃N (0≤x3<1) and including silicon,
a second direction from the second electrode to the first electrode portion crossing a first direction from the first electrode to the second electrode,
the third semiconductor region including a first portion, a second portion, and a third portion,
a direction from the first portion to the second electrode being along the first direction,
a direction from the second portion to the first electrode portion being along the first direction,
the third portion being between the first portion and the second portion,
the first semiconductor region including a first partial region and a second partial region,
the first partial region being between the second partial region and the first electrode portion in the second direction,
the first partial region and the second partial region being between the third portion and the second semiconductor region in the first direction,
a first hydrogen concentration in the first partial region being lower than a second hydrogen concentration in the second partial region.

18. The semiconductor device according to claim 17, wherein
the first semiconductor region further includes a third partial region,
the third partial region is between the first portion and the first electrode in the first direction,
a third hydrogen concentration in the third partial region is lower than the second hydrogen concentration.

19. A method for manufacturing a semiconductor device, the method comprising:
preparing a semiconductor member including a first semiconductor region and a second semiconductor region, the first semiconductor region including Alₓ₁Ga₁₋ₓ₁N (0≤x1<1) and including hydrogen and carbon, the second semiconductor region including Alₓ₂Ga₁₋ₓ₂N (x1<x2≤1);
removing a part of hydrogen included in a first region of the first semiconductor region to cause a first region hydrogen concentration in the first region being lower than a second region hydrogen concentration in a second region of the first semiconductor region; and
forming a recess by removing a part of the second semiconductor region and a part of the second region, and forming an electrode in the recess.
